(19) United States
(12) Patent Application Publication
(10) Pub. No.: US 2010/0052048 A1
(43) Pub. Date: Mar. 4, 2010

(54) SEMICONDUCTOR DEVICE AND METHOD OF MANUFACTURING THE SAME

(76) Inventor: Dong-Woo Kang, Dong-gu (KR)

Correspondence Address: SHERR & VAUGHN, PLLC, 620 HERNDON PARKWAY, SUITE 320, HERNDON, VA, 20170, US

(21) Appl. No.: 12/544,047

(22) Filed: Aug. 19, 2009

(30) Foreign Application Priority Data
Sep. 4, 2008 (KR) 10-2008-0087366

(51) Int. Cl. H01L 29/78; H01L 21/336

(52) U.S. Cl. 257/330; 438/589; 257/E29.262; 257/E21.41

(57) ABSTRACT

A semiconductor device and a method of manufacturing the same includes forming trenches in a semiconductor substrate, and then forming spacers composed of a first polysilicon layer in the trench, and then forming a second polysilicon layer over the spacers and filling the trench. Therefore, even in case of a power MOSFET device having a small line width and a high aspect ratio, generation of voids in the polysilicon when forming a gate is prevented, and thus, device reliability is enhanced.

The present application claims priority under 35 U.S.C. §119 to Korean Patent Application No. 10-2008-0087366, filed on Sep. 4, 2008, which is hereby incorporated by reference in its entirety.

### BACKGROUND

As techniques of a power metal oxide semiconductor field effect transistor (MOSFET) are developed, a line width is decreased and an aspect ratio is gradually increased.

FIG. 1 illustrates a longitudinal-sectional view of a structure of a polysilicon gate of a MOSFET that includes deep trenches 11 formed in semiconductor substrate 10, gate insulating film 12 formed on and/or over the uppermost surface of semiconductor substrate 10 including deep trenches 11, and polysilicon 14 formed on and/or over the uppermost surface of gate insulating film 12 and gap-filling deep trenches 11.

An aspect ratio of deep trenches 11 operating as gates is high, and thus, when deep trenches 11 are gap-filled with polysilicon 14, deep trenches 11 are not smoothly gap-filled. Voids 20 are thereby generated and may cause problems in reliability of a device. For instance, voids 20 located within the polysilicon 14 are difficult to test, and a semiconductor device containing such voids 20, may not be detected in a DC test or a yield analysis. Furthermore, in a power MOSFET product operating at a high voltage, in a burn-in test, an electric field is concentrated in a region where voids 20 are formed. This, in turn, may cause damage to cell regions momentarily.

### SUMMARY

Embodiments relate to a semiconductor device such as a MOSFET having a trench-gate structure, and a method of manufacturing the same.

Embodiments relate to a semiconductor device and a method of manufacturing the same which does not generate voids in polysilicon to gap-fill trenches when forming gates to prevent failure in a burn-in test.

In accordance with embodiments, a method of manufacturing a semiconductor device may include at least one of the following: forming trenches in a semiconductor substrate; and then forming a gate insulating film on and/or over the entire surface of the semiconductor substrate including the trenches; and then forming a first polysilicon layer for gates on and/or over the entire surface of the gate insulating film; and then forming poly spacers in the trenches by etching the first polysilicon layer; and then forming a second polysilicon layer for gates on and/or over the entire surface of the semiconductor substrate to gap-fill the trenches including the poly spacers.

In accordance with embodiments, a method may include at least one of the following: forming a trench in a semiconductor substrate; and then forming a gate insulating film over the entire surface of the semiconductor substrate including the trenches; and then forming a first polysilicon layer over the entire surface of the gate insulating film; and then forming a poly spacers in the trench by etching the first polysilicon layer; and then forming a second polysilicon layer over the entire surface of the semiconductor substrate including the poly spacers to gap-fill the trench.

In accordance with embodiments, a method may include at least one of the following: forming a trench in a semiconductor substrate; and then forming an insulating film over the surface of the semiconductor substrate including the trenches; and then forming a first polysilicon layer over the insulating film; and then forming spacers in the trench by etching the first polysilicon layer; and then forming a second polysilicon layer over the entire surface of the semiconductor substrate including the poly spacers to gap-fill the trench.

In accordance with embodiments, a method may include at least one of the following: forming a trench in a semiconductor substrate; and then reducing the surface roughness of the semiconductor substrate including the trench; and then forming spacers composed of a first polysilicon layer in the trench after reducing the surface roughness of the semiconductor substrate including the trench, wherein the thickness of the sidewalls of the spacers decrease from the bottom of the trench to the top of the trench; and then forming a second polysilicon layer over the spacers and filling the trench.

In accordance with embodiments, a semiconductor device may include at least one of the following: a gate insulating film formed on and/or over the entire surface of a semiconductor substrate including trenches formed in the semiconductor substrate; poly spacers formed on and/or over the uppermost surface of the gate insulating film and in the trenches by a first polysilicon layer for gates; and a second polysilicon layer for gates formed on and/or over the entire surface of the semiconductor substrate to gap-fill the trenches including the poly spacers.

In accordance with embodiments, a semiconductor device may include at least one of the following: a trench formed in a semiconductor substrate; a gate insulating film formed over the surface of trench; spacers composed of a first polysilicon layer formed in the trench and over the gate insulating film such that the thickness of the sidewalls of the poly spacers decreases from the bottom of the trench to the top of the trench; and a gate formed composed of a second polysilicon layer formed over the spacers and filling the trench.

### DRAWINGS

FIG. 1 illustrates a polysilicon gate of a power MOSFET.

Example FIGS. 2A to 2K illustrate a method of manufacturing a semiconductor device in accordance with embodiments.

### DESCRIPTION

As illustrated in example FIGS. 2A to 2E, trenches 46 are formed in semiconductor substrate 40. Trenches may be formed by forming a mask layer on and/or over the entire surface of semiconductor substrate 40. An epitaxial layer may be formed on and/or over the uppermost surface of semiconductor substrate 40 and then the mask layer may be formed on and/or over the uppermost surface of the epitaxial layer. The mask layer may be composed of a photoresist or a hard mask. If trenches 46 are to have a large depth, i.e., a high aspect ratio, it is preferable that the hard mask be used as the mask layer. The hard mask layer may be composed of an oxide film or a multi-layered film such as an oxide-nitride-oxide (ONO) film.

As illustrated in example FIG. 2B, the mask layer is patterned to expose regions where trenches 46 will be formed, thereby forming mask patterns 42.

As illustrated in example FIG. 2C, semiconductor substrate 40 may then be etched using mask pattern 42 as etching mask, thereby forming trenches 44 spaced apart in semiconductor substrate 40. The etching process for forming trenches 44 may be a dry-etching process such as reactive ion etching (RIE).

As illustrated in example FIG. 2D, after the etching process is complete, mask pattern 42 is removed. If mask pattern 42 is composed of a photoresist, mask pattern 42 may be removed by ashing.

As illustrated in example FIG. 2E, the lower portions of trenches 44 are then rounded to have a circular cross-section by performing a second etching process. The second etching process for rounding the lower portion of trenches 44, is selective, and thus, may be omitted.

As illustrated in example FIG. 2F, a dielectric film such as liner oxide film 50 is formed on and/or over the entire surface of semiconductor substrate 40 including trenches 46.

As illustrated in example FIG. 2G, liner oxide film 50 may be removed using an etching process. If a wet-etching process is used, an organic solution or an inorganic solution may be used as an etching solution. For example, the inorganic solution may employ diluted HF (DHF) or buffered HF (BHF), but is not limited thereto. The processes of formation and the removal of liner oxide film 50 serves to reduce the surface roughness of silicon semiconductor substrate 40 in trenches 46. Such processes is selective, and thus, may be omitted. When liner oxide film 50 is formed and then removed under the condition that the lower portions of trenches 46 are rounded by etching, as illustrated in example FIG. 2E, damage to the surface of silicon semiconductor substrate 40 may be minimized.

As illustrated in example FIG. 2H, a second dielectric film such as gate insulating film 60 may then be formed on and/or over the entire surface of semiconductor substrate 40 including trenches 46. Gate insulating film 60 may be composed as an oxide film.

As illustrated in example FIG. 21, first polysilicon layer 80 for gates may then be formed on and/or over the entire surface of gate insulating film 60. First polysilicon layer 80 may not fill gaps in trenches 46. In accordance with embodiments, thickness (t) of first polysilicon layer 80 may be determined by depth (h) of trenches 46 and an aspect ratio (h/w) of trenches 46. Here, w represents a width of trenches 46. Further, the maximum value of the thickness (t) of first polysilicon layer 80 may be less than one-half of the width (w) of trenches 46. For example, the thickness (t) of first polysilicon layer 80 may be in a range between 5 to 10% of the depth (h) of trenches 46.

As illustrated in example FIG. 2J, first polysilicon layer 80 may then be etched, thereby forming poly spacers 80A in trenches 46 and on sidewalls of gate insulating film 60. A slope of poly spacers 80A formed by etching may be determined by the aspect ratio of trenches 48. For instance, the thickness of poly spacers 80A may be reduced going from the bottom portion of trenches 48 to the top of trenches 48. Thereafter, by-products and polymers generated when the first polysilicon layer 80 is etched are removed. For example, the by-products and the polymers may be removed by wet-etching.

As illustrated in example FIG. 2k, second polysilicon layer 82 for gates may then be formed on and/or over the entire surface of semiconductor substrate 40 including poly spacers 80A to gap-fill trenches 48.

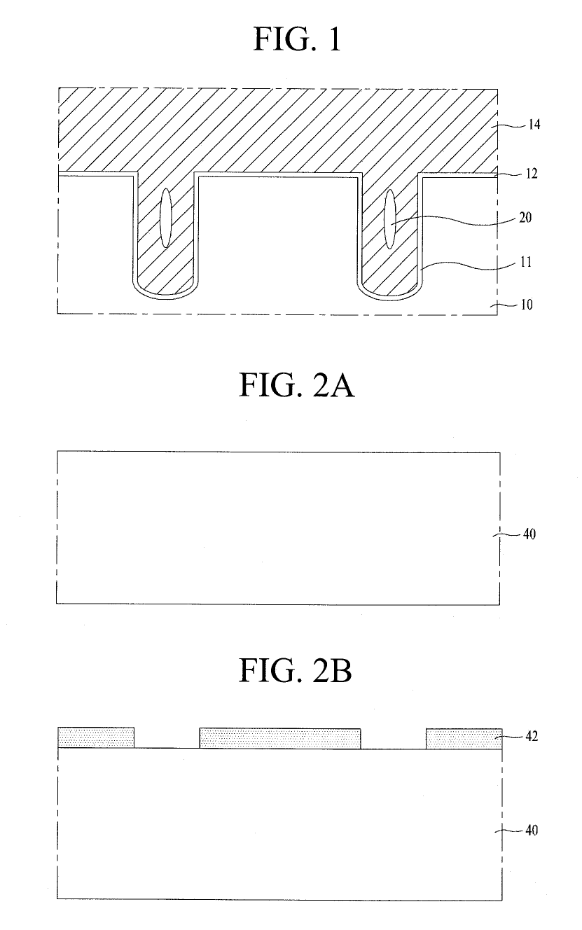

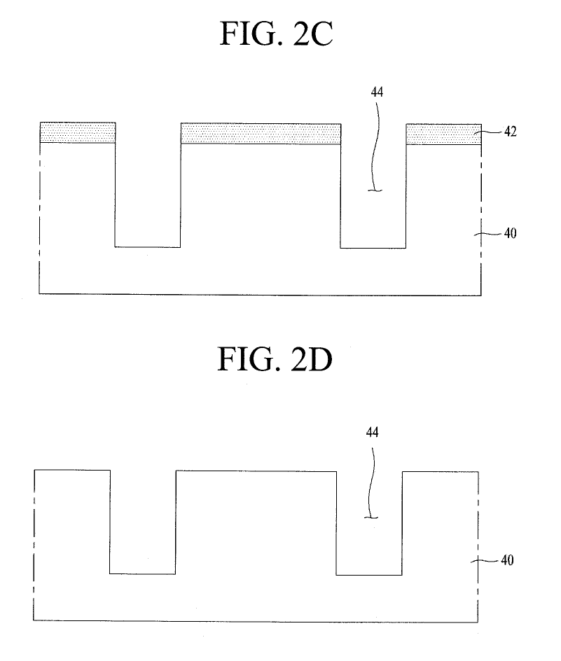

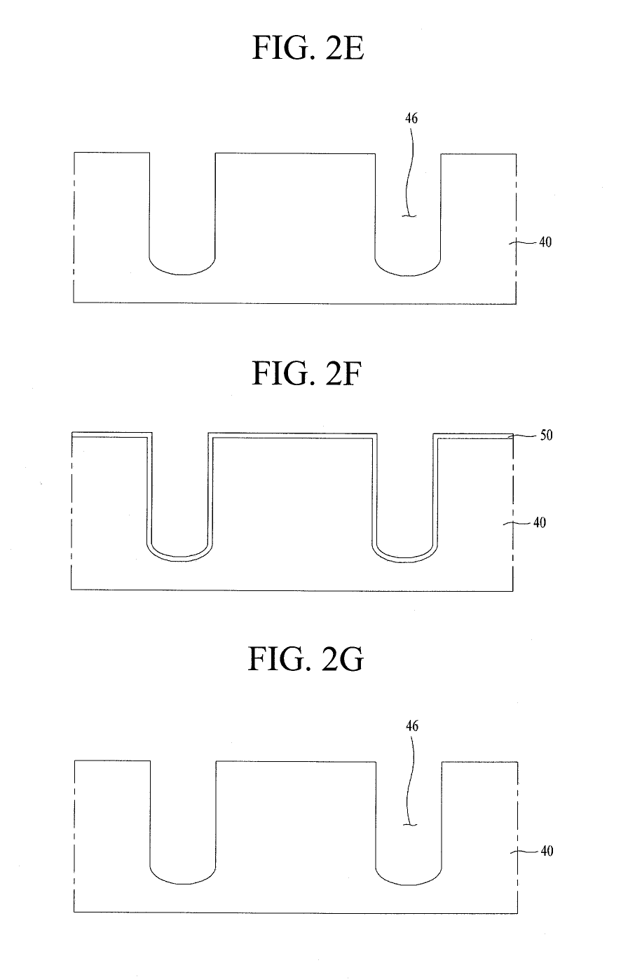

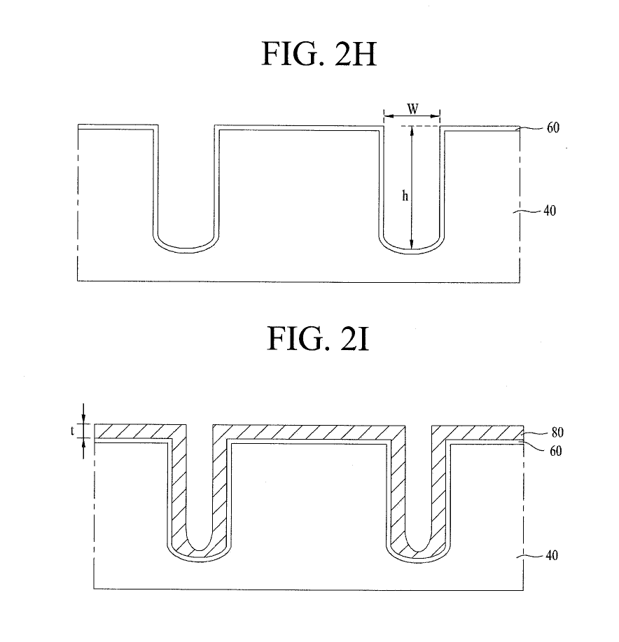

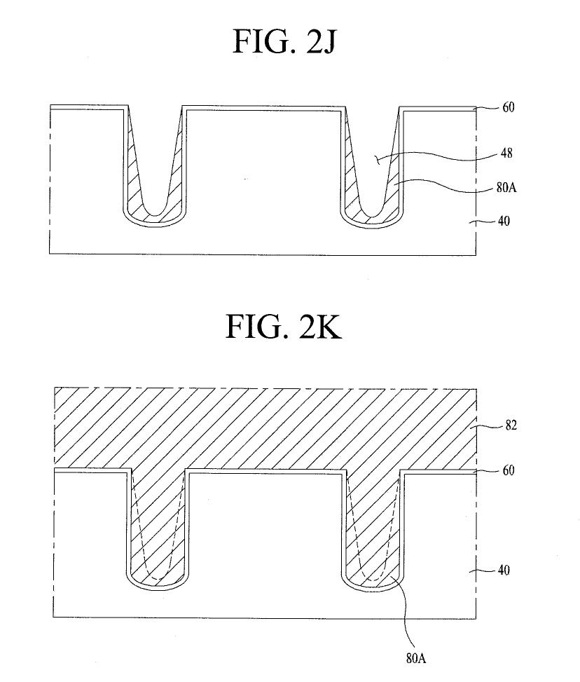

In accordance with embodiments, since second polysilicon layer 82 is formed on and/or over the uppermost surfaces of poly spacers 80A having a sloped-structure, although trenches 48 have a high aspect ratio, generation of voids 20, as illustrated in FIG. 1, is prevented. First polysilicon layer 80 and second polysilicon layer 82 may be conductive films which are formed by depositing polysilicon using chemical vapor deposition (CVD). Thereafter, subsequent processes of etching second polysilicon layer 82 to form a power MOSFET, may then be carried out. These processes are general processes, which are well known to those skilled in the art, and a detailed description thereof will thus be omitted. For example, U.S. Patent Publication No. 2008/0093665 discloses a power MOSFET having a trench-gate structure.

As illustrated in example FIG. 2K, the semiconductor device in accordance with embodiments includes trenches 46 formed in semiconductor substrate 40 and gate insulating film 60 formed on and/or over the entire surface of semiconductor substrate 40 including trenches 46. Poly spacers 80A are formed on and/or over the uppermost surface of gate insulating film 60 within trenches 46 by using first polysilicon layer 80. Poly spacers 80A may be formed having a sloped structure with the thickness increasing from the bottom of trenches 46 to the top of trenches 46. The slope of poly spacers 80A may be determined by the aspect ratio of trenches 46. Second polysilicon layer 82 for gates may then be formed on and/or over the entire surface of semiconductor substrate 40 including the poly spacers 80A by gap-filling trenches 48.

In accordance with embodiments, even in a case of a power MOSFET device having a small line width and a high aspect ratio, a first polysilicon layer may be formed on and/or over a semiconductor substrate including trenches, poly spacers may then be formed in the trenches by etching the first polysilicon layer, and then a second polysilicon layer may be formed on and/or over the semiconductor substrate and the poly spacers and filling the trenches, thereby preventing generation of voids in polysilicon for gates, and thus, preventing poor reliability due to the voids.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device comprising:
forming a trench in a semiconductor substrate; and then
forming a gate insulating film over the surface of the semiconductor substrate including the trench; and then
forming a first polysilicon layer over the entire surface of the gate insulating film; and then
forming poly spacers in the trench by etching the first polysilicon layer; and then
forming a second polysilicon layer over the surface of the semiconductor substrate including the poly spacers to gap-fill the trench.

2. The method of claim 1, wherein the forming the trenches comprises:
forming a mask layer over the entire surface of the semiconductor substrate; and then
forming a mask pattern by patterning the mask layer to expose a trench region; and then
forming the trench by etching the semiconductor substrate using the mask pattern as a mask.

3. The method of claim 2, wherein the mask layer is composed of a photoresist.

4. The method of claim 2, wherein the mask layer is composed of a hard mask.

5. The method of claim 1, further comprising, after forming the trench and before forming the gate insulating film:
performing an etching process on the bottom portion of the trench to form a circular cross-section on the bottom portion of the trenches.

6. The method of claim 1, further comprising, after forming the trench and before forming the gate insulating film:
reducing the surface roughness of the semiconductor substrate.

7. The method of claim 6, wherein reducing the surface roughness of the semiconductor substrate comprises:
forming a liner oxide film on the entire surface of the semiconductor substrate including the trench; and then
removing the liner oxide film.

8. The method of claim 1, wherein the first polysilicon layer has a predetermined thickness.

9. The method of claim 8, wherein the predetermined thickness of the first polysilicon layer is determined by the depth of the trench and an aspect ratio of the trenches.

10. The method of claim 8, wherein the maximum thickness of the first polysilicon layer is less than half of a width of the trench.

11. The method of claim 8, wherein the thickness of the first polysilicon layer is in a range between 5 to 10% of the depth of the trench.

12. The method of claim 1, further comprising, after forming the poly spacers in the trench and before forming the second polysilicon layer:
removing by-products and polymers generated from etching the first polysilicon layer.

13. The method of claim 12, wherein removing the by-products and the polymers is performed by wet-etching.

14. The method of claim 1, wherein the thickness of the sidewalls of the poly spacers decreases from the bottom of the trench to the top of the trench.

15. The method of claim 14, wherein the slope of the poly spacers is determined by an aspect ratio of the trench.

16. A method comprising:
forming a trench in a semiconductor substrate; and then
reducing the surface roughness of the semiconductor substrate including the trench; and then
forming spacers composed of a first polysilicon layer in the trench after reducing the surface roughness of the semiconductor substrate including the trench, wherein the thickness of the sidewalls of the spacers decrease from the bottom of the trench to the top of the trench; and then
forming a second polysilicon layer over the spacers and filling the trench.

17. The method of claim 16, wherein reducing the surface roughness comprises:
forming a second dielectric film over the surface of the semiconductor substrate including the trench; and then
removing the entire second dielectric film.

18. The method of claim 16, further comprising, after forming the spacers and before forming the second polysilicon layer:
removing by-products and polymers generated from forming the spacers.

19. The method of claim 16, wherein the slope of the spacers is determined by an aspect ratio of the trench.

20. A semiconductor device comprising:
a trench formed in a semiconductor substrate;
a gate insulating film formed over the surface of trench;
spacers composed of a first polysilicon layer formed in the trench and over the gate insulating film, wherein the thickness of the sidewalls of the poly spacers decreases from the bottom of the trench to the top of the trench; and
a gate formed composed of a second polysilicon layer formed over the spacers and filling the trench.
